(19) United States
(12) Patent Application Publication
(10) Pub. No.: US 2026/0168834 A1
(43) Pub. Date: Jun. 18, 2026

(54) DETECTOR FOR DETECTING A CHANGE IN VELOCITY OF A FLOW OF ELECTRICALLY CONDUCTIVE FLUID, COMPRISING AN ELECTROMAGNETIC TRANSDUCER

(71) Applicant: COMMISSARIAT A L'ENERGIE ATOMIQUE ET AUX ENERGIES ALTERNATIVES, Paris (FR)

(72) Inventor: Frederic REY, SAINT PAUL LEZ DURANCE (FR)

(21) Appl. No.: 18/982,293

(22) Filed: Dec. 16, 2024

(30) Foreign Application Priority Data
Dec. 19, 2023 (FR) 2314457

(51) Int. Cl. G01F 1/74; H03F 3/19

(52) U.S. Cl. CPC G01F 1/74; H03F 3/19

(57) ABSTRACT

Detector for detecting a change in velocity of a flow of electrically conductive fluid, including an electromagnetic transducer. A detector for detecting a change in velocity of a flow of an electrically conductive fluid, including: an electromagnetic transducer having: a metal cylindrical tube forming a core having a high magnetic permeability, an electric coil, called primary coil, wound around the tube and intended to be electrically powered with direct current, or a permanent magnet arranged around the tube, at least one electric coil, called receiver coil, wound around the tube while being adjacent to the primary coil or to the permanent magnet, at least one envelope detector circuit connected to the receiver coil, comprising at least one diode and one load electrically in series with the diode, the load being made up of a capacitor and of an electrical resistor.

### TECHNICAL FIELD

The present invention concerns the field of instrumentation and measurement, and more particularly that of transducers dedicated to the specific, local velocimetry of electrically conductive fluids.

The invention relates to a detector for detecting a change in velocity of an electrically conductive fluid, comprising an electromagnetic transducer.

The invention applies generally to any electrically conductive fluid. These fluids are for example electrically conductive ionic solutions such as salt water and even more so liquid metals. Usually, these metals are for example sodium, potassium, lead, lithium, aluminium, copper, iron, zinc, titanium and their alloys.

More particularly, the invention applies to measurements in fluids of dense-liquid type having a density in a range of the order from 100 kg·m⁻³ to more than 10 000 kg·m⁻³. The invention is particularly suited for measuring velocities of fluids the melting temperature range of which is the melting temperature range of metals treated, formed or used in liquid form, typically from around −50° C. to more than 1500° C.

One advantageous application envisaged is measuring the velocities of heat-transfer fluids, in particular of nuclear fission and fusion reactors.

### BACKGROUND

In many applications, it is necessary to know the velocity field of a moving electrically conductive fluid.

This is the case in the metal foundry industry in which knowing the velocity field in the foundry moulds and their power-supply circuits makes it possible to predict the quality of the parts produced and to limit rejects. Knowing the flow velocities in fact makes it possible to control and optimize the filling of the foundry moulds.

In the nuclear industry, the velocity field of metal heat-transfer fluids used in the circuits of certain nuclear reactors is a major factor in the stress on metal structures in contact. Thus, knowledge thereof is essential.

It is also a major factor in the thermal exchanges existing in the heat exchangers and in the region of the nuclear fuel of these reactors.

Knowing and analysing the velocity field in keys areas of a reactor (heat exchangers, core output, pump, etc.) is also an indicator of proper functioning and is therefore a means for increasing the safety of and on the whole the possibilities for monitoring these machines.

Scientific experiments using liquid metals in large volumes, and tests performed with a view to knowing flow distributions in exchanger collectors, also require knowledge of the velocity field of the flows involved.

In the various flow zones cited, the flow conditions are three-dimensional. What also most often characterizes these flows is their temperature level, most often of several hundreds of degrees, and the density of the fluids used, the range of which may extend from a few hundreds of kg·m⁻³ to several thousands of kg·m⁻³.

Various velocimetry techniques are known and used for measuring the velocity components of a flow of electrically conductive liquid.

Amongst them, electromagnetic techniques are particularly relevant and robust, in terms of material resistance, with respect to the stresses which are applied thereto by the environment in which the measurement has to be performed. These techniques are all the more beneficial if a dense and chemically reactive fluid is involved, such as liquid metals.

The operating principle of electromagnetic transducers is illustrated by the expression of Ohm's law in the moving fluid subjected to a magnetic field.

It shows that the conductivity σ of the fluid leads to the development of currents (electric current density J) under the action of the velocity of movement u combined with the external magnetic field B:

$$\vec{{J}_{u}} = σ ( \vec{E} + \vec{u} \times \vec{B} ) \qquad [ Equation l ]$$

This occurs even in the absence of an electric field E.

The current densities Jᵤ are a source of a magnetic field Bᵤ. This field Bᵤ deforms the external field B.

It is specified here that, for simplification, the vector symbolized by the letter B, which is the magnetic flux density or magnetic induction, is referred to as magnetic field throughout the application. It is also specified that the various formulae indicated below are written for the purposes of approximating the quasi-permanent systems, making it possible to ignore certain values intervening in the Maxwell equations, such as the movement currents.

To date, measurements of a single velocity component of a flow are commonly performed by electromagnetic transducers, commonly denoted by the acronym ECFM (“Eddy Current Flow Meter”), or else PSFM (“Phase Shift Flow Meter”).

A conventional ECFM, on the whole denoted by the reference 1, is shown in FIGS. 1, 2 and 2A: it is axisymmetric with a central axis Z and typically made up of a core 2, an electric emitter coil, called primary coil 3, and one or two electric receiver coils, called secondary coils 4, 5. The core 2 is formed of a solid rod 20 extending along the central axis Z and of solid discs 21 regularly spaced apart along the central axis (X), the solid rod connecting the solid discs to one another. The primary 3 and secondary 4, 5 coils are wound around the solid rod 20 between two of the solid discs 21.

An alternating current is applied to the primary coil. The flow of this current creates an external magnetic field B in the environment close to the primary coil according to the Maxwell-Ampere equation:

$$\vec{∇} \times \vec{B} = μ \cdot \vec{J} \qquad [ Equation 2 ]$$

where:
\vec{∇}: differential operator
μ: magnetic permeability where μ=μᵣμ₀
μ₀: magnetic permeability of the void
B: passes through the receiver coils.

The primary current is alternating and so B is also alternating. In this way, B induces a voltage in each of the receiver coils according to the Maxwell-Faraday equation:

$$\vec{∇} \times \vec{E} = - \frac{\partial \vec{B}}{\partial t} \qquad [ Equation 3 ]$$

where:
\vec{E}: electric field.

Moreover, B also leads to the development of induced current densities Ji in the fluid and in any surrounding electrical conductor subjected to this magnetic field, including the metal of the tubes. FIGS. 3 and 4 show the development of current densities induced under the action of the external magnetic field, in the absence of a flow velocity, for an ECFM, for one secondary coil 4 and for two secondary coils 4, 5, respectively.

The current densities Ji create in turn a magnetic field Bi deforming the external field B. Thus, the field B is not the same depending on whether or not the ECFM is surrounded by an electrically conductive fluid.

In the absence of fluid movement, the one or more receiver coils deliver voltages which are functions of the external magnetic field B and of the field Bi.

In the presence of a fluid movement, new current densities Ju appear and are the source of a magnetic field Bu. This new field modifies B which is, as it were, blown by the flow of conductive fluid and deforms in the direction of the flow of the latter, as illustrated in FIGS. 5A, 5B and 6.

The magnetic flux passing through the one or more receiver coils depends on the flow velocity.

The one or more receiver coils therefore deliver voltages translating the influence of the magnetic fields Bᵢ and Bᵤ which deform the external field B.

Digital simulations illustrate this. FIGS. 7A and 7B are digital simulations of the magnetic field around an ECFM in the absence and in the presence, respectively, of a flow velocity of electrically conductive fluid.

Analysing the voltages delivered by the receiver coils makes it possible to determine the flow velocity of the fluid moving in the zone of action of the magnetic field B.

As shown in FIG. 8, although the single receiver coil 4 of an ECFM 1 is upstream with respect to the direction of the flow of fluid, it sees a drop in magnetic flux when the velocity increases (and vice versa). The alternating voltage e₁ that it delivers decreases by Δe₁.

The alternating voltage e₁ provided by the ECFM is the image of the flow velocity (with an indication of the relative direction by virtue of comparing the amplitude of the current signal with the amplitude of the signal without velocity).

In addition to this, in the case of an ECFM having two receiver coils, the downstream receiver coil sees an increase in the flux which passes through it as the fluid velocity increases. Its voltage e₂ grows by Δe₂.

$$Hence \vert Δ {e}_{2} \vert = \vert Δ {e}_{1} \vert$$

Generally, the two receiver coils 4, 5 of an ECFM are electrically coupled in anti-series, as shown in FIG. 9.

In this way, the signal V provided by the ECFM having two coils is given by:

$$V = \vert {e}_{2} \vert - \vert {e}_{1} \vert$$

where |eₓ|: modulus or amplitude of the voltage eₓ.

The signal V is proportional to the velocity component of the flow projected on the axis of revolution of the ECFM.

In practice, preference is given to the ECFM having two receiver coils because the combined use of the voltages delivered by these two coils makes it possible to double the sensitivity and eliminate the dependency of the response of the ECFM on non-relevant values such as the temperature:

$$V = ( \vert {e}_{2} \vert - \vert {e}_{1} \vert ) / ( \vert {e}_{2} \vert + \vert {e}_{1} \vert )$$

The sign of V gives the direction of the velocity without the need for a comparison with the amplitude of the signal without flow velocity.

When it comes to arranging the ECFMs relative to the flow of fluid, they may be internal to the flow, that is to say positioned on the axis of a tube in the middle of the flow to be characterized: [1]. An ECFM is thus within the flow of fluid, the latter being peripheral to the ECFM.

In practice, as shown in FIG. 10, an internal ECFM 1 is generally placed in the centre of an annular space, delimited by two concentric tubes T1, T2, through which flows the fluid F whose velocities it is sought to measure.

Other ECFMs may be external to the flow. The coils and the core of the external ECFMs are thus arranged around the flow of fluid for which it is desired to measure the velocities.

In practice, an external ECFM is placed around a tube so as to measure the velocity of the fluid which flows through this tube: [2].

When the ECFMs are used to evaluate the velocity of a fluid flowing through a tube, whether they be internal or external to the latter, they can only measure one velocity component which is that along the axis of the tube and therefore along their axis of axisymmetry X. Specifically, the tube guides the flow of the fluid and gives it its main direction.

Generally, the processing of the signal of a conventional ECFM or of the flowmeters presently available can be complex to perform.

There is therefore a need to propose a simplified solution for measuring velocity, and processing the associated signal, of a flow of electrically conductive fluids which may be dense, for a range of high velocities and/or at high temperatures, and to do so even in large volumes.

The aim of the invention is to at least partially meet this need.

### SUMMARY OF THE INVENTION

To this end, the object of the invention is a detector for detecting a change in velocity of a flow of an electrically conductive fluid, comprising:
an electromagnetic transducer comprising:
   a metal cylindrical tube forming a core having a high magnetic permeability,
   an electric coil, called primary coil, wound around the tube and intended to be electrically powered with direct current, or a permanent magnet arranged around the tube,
   at least one electric coil, called receiver coil, wound around the tube while being adjacent to the primary coil or to the permanent magnet,
at least one envelope detector circuit connected to the receiver coil, comprising at least one diode and one load electrically in series with the diode, the load being made up of a capacitor and of an electrical resistor.

According to a first embodiment, the detector comprises a single envelope detector circuit.

Alternatively, according to a second embodiment, the detector comprises two envelope detector circuits in parallel with the receiver coil, the diode of one of the two circuits being mounted in the opposite direction to the diode of the other of the two circuits. A detector according to this embodiment makes it possible to detect both the increasing and the decreasing in the velocity of the flow of the fluid.

Advantageously, the detector comprises an electronic device connected to the envelope detector circuit(s) so as to detect the voltage threshold(s) at the output of the capacitor(s). The electronic device is preferably a Schmitt trigger.

Preferably, the core is of a low electrical conductivity so as to limit the losses induced by the variable magnetic induction, namely the joule losses associated with the flow of the induced current and the losses by hysteresis.

Thus, the invention essentially consists in a detector for detecting a change in unidirectional velocity of an electrically conductive fluid, which comprises an electromagnetic transducer which operates either with a primary coil powered with direct current, or with a permanent magnet.

An envelope detector circuit is very simple as a device for processing the signal received by the receiver coil.

A detector according to the invention makes it possible to measure the changes in velocity of a fluid the nominal velocity of which may be from a few millimetres per second to several metres per second.

Furthermore, it is suited for measuring changes in velocity of electrically conductive liquids which are dense, typically having a density of the order from 100 to more than 10 000 kg·m⁻³, and/or which have a high temperature, typically in the range of the melting temperatures of metals treated, formed or used in liquid form.

Finally, a detector according to the proposed invention makes it possible to overcome the identified limitations of the prior-art devices and has many advantages including:
processing the signals that it produces, in a very simple manner compared to existing flowmeters and in a considerably less complex manner than the reconstruction algorithms needed for the ECFMs according to the prior art and for tomographic measurement methods;
the possibility of being positioned within the flow to be characterized in the zone to be studied.

Other advantages and features will become more clearly apparent upon reading the detailed description, which is provided by way of non-limiting illustration, with reference to the following figures.

### BRIEF DESCRIPTION OF THE DRAWINGS

FIG. 1 is a schematic side view of an Eddy Current Flow Meter (ECFM) according to the prior art having one receiver (secondary) coil.

FIG. 2 is a schematic side view of an ECFM according to the prior art having two receiver (secondary) coils.

FIG. 2A is a longitudinal sectional view of FIG. 2.

FIG. 3 shows FIG. 1 again and illustrates the development of current densities induced under the action of the external magnetic field in the absence of flow velocity.

FIG. 4 shows FIG. 2 again and illustrates the development of current densities induced under the action of the external magnetic field in the absence of flow velocity.

FIGS. 5A and 5B show FIG. 1 again and illustrate the development of current densities induced under the action of the external magnetic field in the presence of a flow velocity.

FIG. 6 shows FIG. 2 again and illustrates the development of current densities induced under the action of the external magnetic field in the presence of a flow velocity.

FIGS. 7A and 7B are representations of digital simulations of the magnetic field around an ECFM according to the prior art in the absence and in the presence, respectively, of a flow velocity of electrically conductive fluid.

FIG. 8 shows FIG. 1 again and illustrates the voltage across the terminals of the receiver coil of the ECFM according to the prior art.

FIG. 9 shows FIG. 2 again and illustrates, on the one hand, a preferred electrical coupling of the receiver coils in anti-series and the voltages across the terminals of the coils the final voltage observed across the terminals of the ECFM according to the prior art.

FIG. 10 is a reprographic reproduction of an ECFM according to the prior art such as arranged internally in an implantation tube for measuring a one-dimensional velocity of a flowing fluid F.

FIG. 11 is a schematic side view of an electromagnetic transducer of a detector for detecting a change in velocity according to the invention having a primary coil powered with direct current and a receiver (secondary) coil.

FIG. 12 is a schematic side view of an electromagnetic transducer of a detector for detecting a change in velocity according to the invention having a permanent magnet and a receiver (secondary) coil.

FIG. 13 is a schematic view of an envelope detector circuit for a detector according to the invention.

FIG. 14 is a schematic view of a double envelope detector circuit for a detector according to the invention.

### DETAILED DESCRIPTION

Throughout the present application, the terms “upstream” and “downstream” are to be understood with reference to the direction of the flow of a fluid around the transducer along the axis Z.

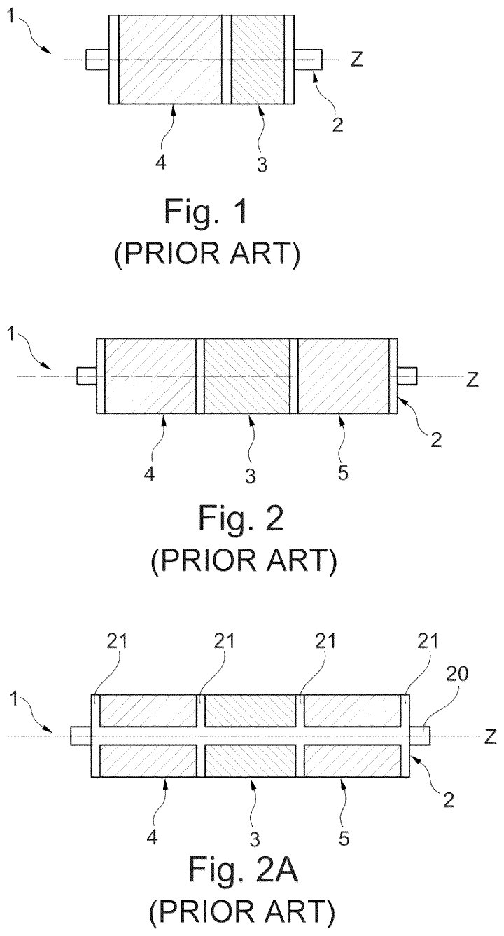

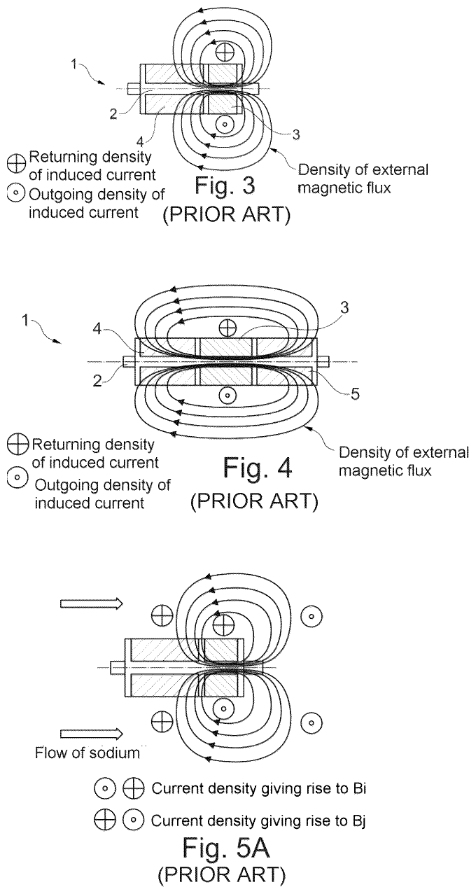

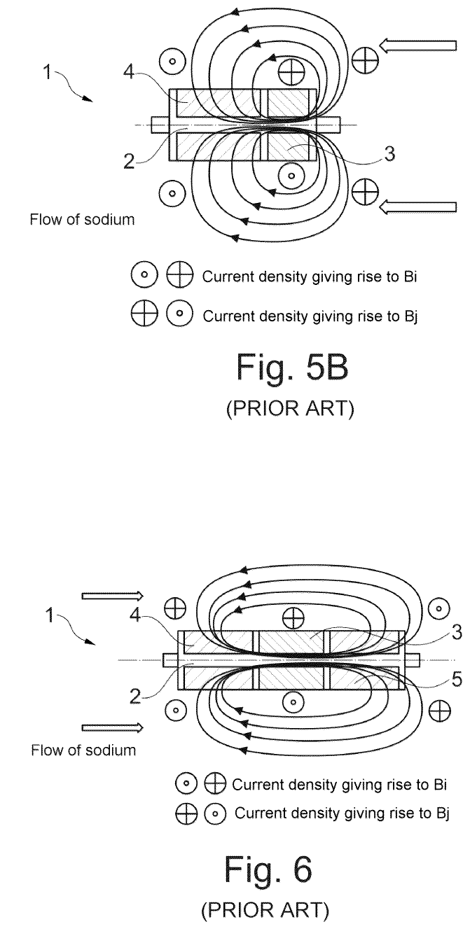

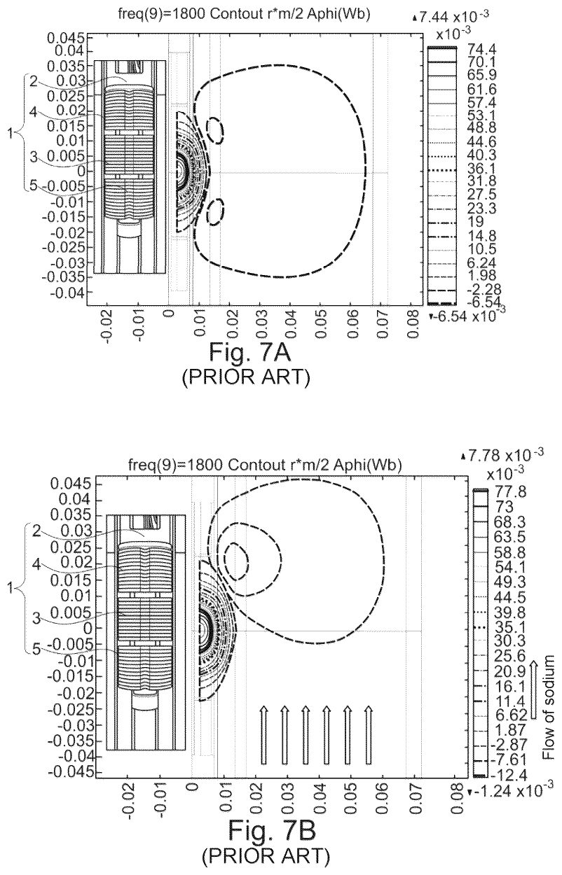

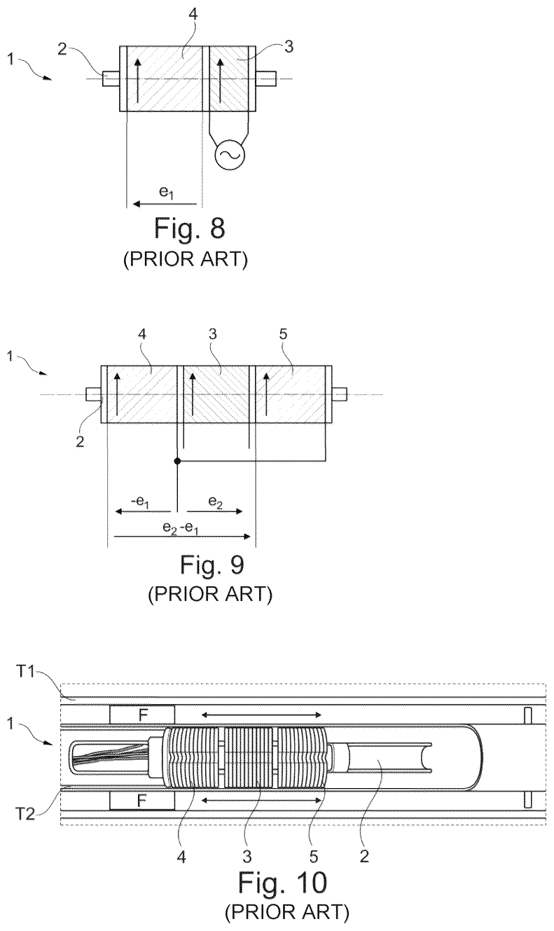

FIGS. 1 to 10 have already been described in the preamble. They will therefore not be discussed in detail below.

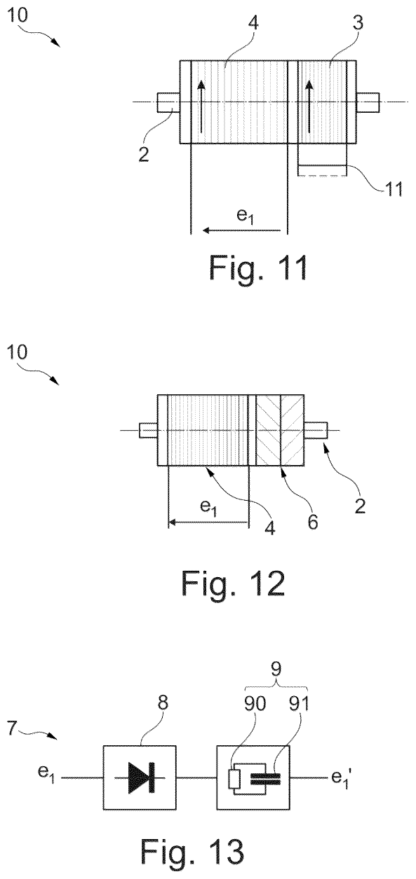

FIG. 11 shows an electromagnetic transducer 10 of a detector according to the invention, intended to measure the change in velocity of a flow of an electrically conductive fluid.

The transducer 10 is axisymmetric with a central axis X and is typically made up of a core 2 having a high magnetic permeability, an electric emitter coil, called primary coil 3, and an electric receiver coil, called secondary coil 4.

The core 2 is formed of a tube extending along the central axis X.

The primary 3 and secondary 4 coils are wound around the tube 2.

An alternative to the transducer of FIG. 11 is shown in FIG. 12: instead of a primary coil to be powered with direct current, a permanent magnet 6 may be arranged around the core 2, adjacent to the secondary coil 4.

An envelope detector circuit 7 is connected to the terminals of the secondary coil 4. As illustrated in FIG. 13, such a circuit 7 is made up of a diode 8 connected in series with a load 9 made up of a resistor 90 in parallel with a capacitor 91.

The envelope detector circuit 7 is connected to an electronic device having threshold exceedance detection, not shown. This electronic device may be a Schmitt trigger.

The operation of the detector having an electromagnetic transducer 10 and an envelope detector circuit 7 is now explained.

In the event of a change in velocity of the fluid surrounding the transducer 10, the receiver coil 4 is the site of an induced electromotive force caused by the change in the magnetic flux coming either from the primary coil 3 powered with current, or from the permanent magnet 6.

The amplitude of the voltage signal e₁ delivered by the receiver coil 4 depends on the amplitude of the change in velocity. The velocity component to which the detector is sensitive is that which is in parallel with the central axis (Z).

The sign of the signal of the detector provides information about whether the change in velocity is positive or negative (increase or decrease in the velocity).

The coil 4 therefore delivers a voltage e₁ which is rectified by the diode 8 and charges the capacitor 91. The resistor 90 allows the capacitor to be discharged gradually so as to limit over a desired time the duration of existence of a voltage e′₁, which is the image of the envelope of the signal resulting from the values of e₁ over time. These values e′₁ are detected by the Schmitt trigger.

Thus, the existence of a voltage e₁ is detected in a very simple manner and can be temporarily stored, for a duration which is a function of the capacity of the capacitor 91 and of the ohmic resistance of the resistor 90.

With a single envelope circuit 7 according to FIG. 13, only the increase or the reduction in velocity of the fluid flowing around the transducer is obtained.

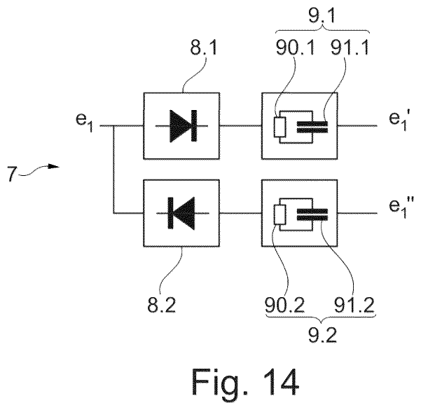

A double envelope circuit 7 variant is illustrated in FIG. 14: two envelope detector circuits 7 are connected electrically in parallel with the receiver coil 4 here. Each of the two circuits is made up of a diode 8.1; 8.2 connected in series with a load 9.1; 9.2 made up of a resistor 90.1; 90.2 in parallel with a capacitor 91.1; 91.2.

The diode 8.1 of one of the two circuits is mounted in the opposite direction to the diode 8.2 of the other of the two circuits.

With this double circuit 7, detection of both the increase and decrease in the velocity is obtained. The voltages e′₁ and e″₁ provide information about the existence of a positive change, for example given by e′₁, and of a negative change, for example given by e″₁. These output voltage values e′₁, e″₁ are each detected by a Schmitt trigger.

Other variants and improvements may be envisaged without departing from the scope of the invention.

### LIST OF CITED REFERENCES

[1]: https://www.hzdr.de/db/Cms?pOid=55433&pNid=226
[2]: https://ieeexplore.ieee.org/stamp/stamp.jsp?arnumber=9768530

1. A detector for detecting a change in velocity of a flow of an electrically conductive fluid, comprising:
an electromagnetic transducer comprising:
a metal cylindrical tube forming a core having a high magnetic permeability,
an electric coil, called primary coil, wound around the tube and intended to be electrically powered with direct current, or a permanent magnet arranged around the tube,
at least one electric coil, called receiver coil, wound around the tube while being adjacent to the primary coil or to the permanent magnet,
at least one envelope detector circuit connected to the receiver coil, comprising at least one diode and one load electrically in series with the diode, the load being made up of a capacitor and of an electrical resistor.

2. The detector according to claim 1, comprising a single envelope detector circuit.

3. The detector according to claim 1, comprising two envelope detector circuits in parallel with the receiver coil, the diode of one of the two circuits being mounted in the opposite direction to the diode of the other of the two circuits.

4. The detector according to one of claim 1, comprising an electronic device connected to the envelope detector circuit(s) so as to detect the voltage threshold(s) (e′₁, e″₁) at the output of the capacitor(s).

5. The detector according to claim 4, the electronic device being a Schmitt trigger.

6. Use of a detector according to claim 1 for measuring a change in velocity of a flow of an electrically conductive fluid, such as a liquid metal of a nuclear reactor.
